(19) United States
(12) Patent Application Publication
(10) Pub. No.: US 2008/0100202 A1
(43) Pub. Date: May 1, 2008

(54) PROCESS FOR FORMING OLED CONDUCTIVE PROTECTIVE LAYER

(76) Inventor: Ronald S. Cok, Rochester, NY (US)

Correspondence Address: Andrew J. Anderson;Patent Legal Staff, Eastman Kodak Company, 343 State Street, Rochester, NY, 14650-2201, US

(21) Appl. No.: 11/555,428

(22) Filed: Nov. 1, 2006

(51) Int. Cl. H05B 33/00; H01L 51/50

(52) U.S. Cl. 313/503; 313/512; 427/66

(57) ABSTRACT

A process is disclosed for forming an OLED device, comprising: providing a substrate having a first electrode and one or more organic layers formed thereon, at least one organic layer being a light-emitting layer; forming a conductive protective layer over the one or more organic layers opposite the first electrode by employing a vapor deposition process comprising alternately providing a first reactive gaseous material and a second reactive gaseous material, wherein the first reactive gaseous material is capable of reacting with the organic layers treated with the second reactive gaseous material, wherein the temperature of the gaseous materials and organic layers are less than 140 degrees C. while the gases are reacting and wherein the resistivity of the protective layer is greater than 10⁶ ohm per square; and forming a second electrode over the conductive protective layer by sputter deposition.

### FIELD OF THE INVENTION

The present invention relates to organic light-emitting diode (OLED) devices, and more particularly, to a process for forming a conductive protective layer in an OLED device by vapor deposition.

### BACKGROUND OF THE INVENTION

Organic light-emitting diodes (OLEDs) are a promising technology for flat-panel displays and area illumination lamps. The technology relies upon thin-film layers of organic materials coated upon a substrate. OLED devices generally can have two formats known as small-molecule devices such as disclosed in U.S. Pat. No. 4,476,292 and polymer OLED devices such as disclosed in U.S. Pat. No. 5,247,190. Either type of OLED device may include, in sequence, an anode, an organic EL element, and a cathode. The organic EL element disposed between the anode and the cathode commonly includes an organic hole-transporting layer (HTL), an emissive layer (EL) and an organic electron-transporting layer (ETL). Holes and electrons recombine and emit light in the EL layer. Tang et al. (Appl. Phys. Lett., 51, 913 (1987), Journal of Applied Physics, 65, 3610 (1989), and U.S. Pat. No. 4,769,292 demonstrated highly efficient OLEDs using such a layer structure. Since then, numerous OLEDs with alternative layer structures, including polymeric materials, have been disclosed and device performance has been improved. However, the materials comprising the organic EL element are sensitive and, in particular, are easily destroyed by moisture and high temperatures (for example greater than 140 degrees C.).

OLEDs are thin-film devices comprising an anode, a cathode, and an organic EL element disposed between the anode and the cathode. In operation, an electrical voltage is applied between the anode and the cathode causing electrons to inject from the cathode and holes to inject from the anode. When properly constructed, the injected electrons and holes recombine in the light emitting layer within the organic EL element and the recombination of these charge carriers causes light to emit from the device. Typically, the organic EL element is about 100˜500 nm in thickness, the voltage applied between the electrodes is about 3˜10 volts, and the operating current is about 1˜20 mA/cm².

Because of the small separation between the anode and the cathode, the OLED devices are prone to shorting defects. Pinholes, cracks, steps in the structure of OLED devices, and roughness of the coatings, etc. can cause direct contacts between the anode and the cathode or to cause the organic layer thickness to be smaller in these defective areas. These defective areas provide low resistance pathways for the current to flow causing less or, in the extreme cases, no current to flow through the organic EL element. The luminous output of the OLED devices is thereby reduced or eradicated. In a multi-pixel display device, the shorting defects could result in dead pixels that do not emit light or emit below average intensity of light causing reduced display quality. In lighting or other low-resolution applications, the shorting defects could result in a significant fraction of area non-functional. Because of the concerns on shorting defects, the fabrication of OLED devices is typically done in clean rooms. However, even a clean environment cannot be completely effective in eliminating the shorting defects. In many cases the thickness of the organic layers is also increased more than what is actually needed for functioning devices in order to increase the separation between the two electrodes and thereby reduce the number of shorting defects. These approaches add costs to OLED device manufacturing, and even with these approaches the shorting defects cannot be totally eliminated. Moreover, such thicker layers may increase the operating voltage of the device and thereby reducing efficiency.

Moreover, the deposition of electrode material over organic layers can compound the problem in certain circumstances. In a top-emitter OLED device architecture, a transparent electrode through which light is emitted is formed over the organic layers. Such electrodes typically comprise metal oxides, for example indium tin oxide (ITO) and are deposited by sputtering. The sputtering process can damage the underlying organic materials. Also, the presence of any particulate contamination can create openings in the electrode layer when such directional deposition processes such as sputtering are employed.

JP2002100483A discloses a method to reduce shorting defects due to local protrusions of crystalline transparent conductive films of an anode by depositing an amorphous transparent conductive film over the crystalline transparent conductive film. It alleged that the smooth surface of the amorphous film could prevent the local protrusions from the crystalline films from forming shorting defects or dark spots in the OLED device. The effectiveness of the method is doubtful since the vacuum deposition process used to produce the amorphous transparent conductive films does not have leveling functions and the surface of the amorphous transparent conductive films is expected to replicate that of the underlying crystalline transparent conductive films. Furthermore, the method does not address the pinhole problems due to dust particles, flakes, structural discontinuities, or other causes that are prevalent in OLED manufacturing processes.

JP2002208479A discloses a method to reduce shorting defects by laminating an intermediate resistor film made of a transparent metal oxide of which, the film thickness is 10 nm-10 μm, the resistance in the direction of film thickness is 0.01-2 Ω-cm2, and the ionization energy at the surface of the resistor film is 5.1 eV or more, on the whole or partial of light emission area on a positive electrode or a negative electrode formed into transparent electrode pattern which is formed on a transparent substrate made of glass or resin. While the method has its merits, the specified resistivity range cannot effectively reduce leakage due to shorting in many OLED displays or devices. Furthermore, the ionization energy requirement severely limits the choice of materials and it does not guarantee appropriate hole injection that is known to be critical to achieving good performance and lifetime in OLED devices. Furthermore, the high ionization energy materials cannot provide electron injection and therefore cannot be applied between the cathode and the organic light emitting layers. It is often desirable to apply the resistive film between the cathode material and the organic light emitting layers or to apply the resistive film both between the cathode and the organic light emitting materials and between the anode and the organic light emitting materials.

It has been found that one of the key factors that limits the efficiency of OLED devices is the inefficiency in extracting the photons generated by the electron-hole recombination out of the OLED devices. Due to the relatively high optical indices of the organic and transparent electrode materials used, most of the photons generated by the recombination process are actually trapped in the devices due to total internal reflection. These trapped photons never leave the OLED devices and make no contribution to the light output from these devices. Because light is emitted in all directions from the internal layers of the OLED, some of the light is emitted directly from the device, and some is emitted into the device and is either reflected back out or is absorbed, and some of the light is emitted laterally and trapped and absorbed by the various layers comprising the device. In general, up to 80% of the light may be lost in this manner.

A typical OLED device uses a glass substrate, a transparent conducting anode such as indium-tin-oxide (ITO), a stack of organic layers, and a reflective cathode layer. Light generated from such a device may be emitted through the glass substrate. This is commonly referred to as a bottom-emitting device. Alternatively, a device can include a substrate, a reflective anode, a stack of organic layers, and a top transparent cathode layer. Light generated from such an alternative device may be emitted through the top transparent electrode. This is commonly referred to as a top-emitting device. In these typical devices, the index of the ITO layer, the organic layers, and the glass is about 1.8-2.0, 1.7, and 1.5 respectively. It has been estimated that nearly 60% of the generated light is trapped by internal reflection in the ITO/organic EL element, 20% is trapped in the glass substrate, and only about 20% of the generated light is actually emitted from the device and performs useful functions.

A variety of techniques have been proposed to improve the out-coupling of light from thin-film light emitting devices. One such technique, taught in US 2006/0186802 entitled “OLED Device Having Improved Light Output” by Cok et al, which is hereby incorporated in its entirety by reference, describes the use of scattering layers formed over the transparent electrode of a top-emitter OLED device. It also teaches the use of very thin layers of transparent encapsulating materials deposited on the electrode to protect the electrode from the scattering layer deposition. Preferably, the layers of transparent encapsulating material have a refractive index comparable to the refractive index range of the transparent electrode and organic layers, or is very thin (e.g., less than about 0.2 micron) so that wave guided light in the transparent electrode and organic layers will pass through the layers of transparent encapsulating material and be scattered by the scattering layer.

It is also well known that OLED materials are subject to degradation in the presence of environmental contaminants, in particular moisture. Organic light-emitting diode (OLED) display devices typically require humidity levels below about 1000 parts per million (ppm) to prevent premature degradation of device performance within a specified operating and/or storage life of the device. Control of the environment to this range of humidity levels within a packaged device is typically achieved by encapsulating the device with an encapsulating layer and/or by sealing the device, and/or providing a desiccant within a cover. Desiccants such as, for example, metal oxides, alkaline earth metal oxides, sulfates, metal halides, and perchlorates are used to maintain the humidity level below the above level. See for example U.S. Pat. No. 6,226,890 B1 issued May 8, 2001 to Boroson et al. describing desiccant materials for moisture-sensitive electronic devices. Such desiccating materials are typically located around the periphery of an OLED device or over the OLED device itself.

In alternative approaches, an OLED device is encapsulated using thin multi-layer coatings of moisture-resistant material. For example, layers of inorganic materials such as metals or metal oxides separated by layers of an organic polymer may be used. Such coatings have been described in, for example, U.S. Pat. Nos. 6,268,695, 6,413,645 and 6,522,067. A deposition apparatus is further described in WO2003090260 A2 entitled “Apparatus for Depositing a Multilayer Coating on Discrete Sheets”. WO0182390 entitled “Thin-Film Encapsulation of Organic Light-Emitting Diode Devices” describes the use of first and second thin-film encapsulation layers made of different materials wherein one of the thin-film layers is deposited at 50 nm using atomic layer deposition (ALD) discussed below. According to this disclosure, a separate protective layer is also employed, e.g. parylene. Such thin multi-layer coatings typically attempt to provide a moisture permeation rate of less than 5×10⁻⁶ gm/m²/day to adequately protect the OLED materials. In contrast, typically polymeric materials have a moisture permeation rate of approximately 0.1 gm/m²/day and cannot adequately protect the OLED materials without additional moisture blocking layers. With the addition of inorganic moisture blocking layers, 0.01 gm/m²/day may be achieved and it has been reported that the use of relatively thick polymer smoothing layers with inorganic layers may provide the needed protection. Thick inorganic layers, for example 5 microns or more of ITO or ZnSe, applied by conventional deposition techniques such as sputtering or vacuum evaporation may also provide adequate protection, but thinner conventionally coated layers may only provide protection of 0.01 gm/m²/day. WO2004105149 A1 entitled “Barrier Films for Plastic Substrates Fabricated By Atomic Layer Deposition” published Dec. 2, 2004 describes gas permeation barriers that can be deposited on plastic or glass substrates by atomic layer deposition (ALD). Atomic Layer Deposition is also known as Atomic Layer Epitaxy (ALE) or atomic layer CVD (ALCVD), and reference to ALD herein is intended to refer to all such equivalent processes. The use of the ALD coatings can reduce permeation by many orders of magnitude at thicknesses of tens of nanometers with low concentrations of coating defects. These thin coatings preserve the flexibility and transparency of the plastic substrate. Such articles are useful in container, electrical, and electronic applications. However, such protective layers also cause additional problems with light trapping in the layers since they may be of lower index than the light-emitting organic layers.

Among the techniques widely used for thin-film deposition are Chemical Vapor Deposition (CVD) that uses chemically reactive molecules that react in a reaction chamber to deposit a desired film on a substrate. Molecular precursors useful for CVD applications comprise elemental (atomic) constituents of the film to be deposited and typically also include additional elements. CVD precursors are volatile molecules that are delivered, in a gaseous phase, to a chamber in order to react at the substrate, forming the thin film thereon. The chemical reaction deposits a thin film with a desired film thickness.

Common to most CVD techniques is the need for application of a well-controlled flux of one or more molecular precursors into the CVD reactor. A substrate is kept at a well-controlled temperature under controlled pressure conditions to promote chemical reaction between these molecular precursors, concurrent with efficient removal of byproducts. Obtaining optimum CVD performance requires the ability to achieve and sustain steady-state conditions of gas flow, temperature, and pressure throughout the process, and the ability to minimize or eliminate transients.

Atomic layer deposition (“ALD”) is an alternative film deposition technology that can provide improved thickness resolution and conformal capabilities, compared to its CVD predecessor. In the present disclosure, the term “vapor deposition” includes both ALD and CVD methods. The ALD process segments the conventional thin-film deposition process of conventional CVD into single atomic-layer deposition steps. Advantageously, ALD steps are self-terminating and can deposit precisely one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the complete absence of the other precursor or precursors of the reaction. In practice in any process it is difficult to avoid some direct reaction of the different precursors leading to a small amount of chemical vapor deposition reaction. The goal of any process claiming to perform ALD is to obtain device performance and attributes commensurate with an ALD process while recognizing that a small amount of CVD reaction can be tolerated.

In ALD applications, typically two molecular precursors are introduced into the ALD reactor in separate stages. For example, a metal precursor molecule, MLₓ, comprises a metal element, M that is bonded to an atomic or molecular ligand, L. For example, M could be, but would not be restricted to, Al, W, Ta, Si, Zn, etc. The metal precursor reacts with the substrate, when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous precursor molecule effectively reacts with all of the ligands on the substrate surface, resulting in deposition of a single atomic layer of the metal:

substrate-AH+MLₓ→substrate-AMLₓ₋₁+HL (1)

where HL is a reaction by-product. During the reaction, the initial surface ligands, AH, are consumed, and the surface becomes covered with L ligands, which cannot further react with metal precursor MLₓ. Therefore, the reaction self-terminates when all the initial AH ligands on the surface are replaced with AMLₓ₋₁ species. The reaction stage is typically followed by an inert-gas purge stage that eliminates the excess metal precursor from the chamber prior to the separate introduction of the other precursor.

A second molecular precursor then is used to restore the surface reactivity of the substrate towards the metal precursor. This is done, for example, by removing the L ligands and redepositing AH ligands. In this case, the second precursor typically comprises the desired (usually nonmetallic) element A (i.e., O, N, S), and hydrogen (i.e., H₂O, NH₃, H₂S). The next reaction is as follows:

substrate-A-ML+AH_{y}→substrate-A-M-AH+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, an ALD process requires alternating in sequence the flux of chemicals to the substrate. The representative ALD process, as discussed above, is a cycle having four different operational stages:

1. MLₓ reaction;

2. MLₓ purge;

3. AH_{y} reaction; and

4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all identical in chemical kinetics, deposition per cycle, composition, and thickness. However, such processes are expensive and lengthy, requiring vacuum chambers and repeated cycles of filling a chamber with a gas and then removing the gas.

ALD and CVD processes as conventionally taught, typically employ heated substrates on which the materials are deposited. These heated substrates are typically at temperatures above the temperatures organic materials employed in OLED devices can tolerate. In addition, the films formed in such processes may be energetic and very brittle, such that the subsequent deposition of any materials over the films destroys the film's integrity.

Thus, a need exists for an OLED architecture that decreases damage due to electrode deposition, improves yields, particularly in the presence of particulate contaminants, increases lifetime, and improves the efficiency of light emission.

### SUMMARY OF THE INVENTION

In accordance with one embodiment, the invention is directed towards a process for forming an OLED device, comprising: providing a substrate having a first electrode and one or more organic layers formed thereon, at least one organic layer being a light-emitting layer; forming a conductive protective layer over the one or more organic layers opposite the first electrode by employing a vapor deposition process comprising alternately providing a first reactive gaseous material and a second reactive gaseous material, wherein the first reactive gaseous material is capable of reacting with the organic layers treated with the second reactive gaseous material, wherein the temperature of the gaseous materials and organic layers are less than 140 degrees C. while the gases are reacting and wherein the resistivity of the protective layer is greater than 10⁶ ohm per square; and forming a second electrode over the conductive protective layer by sputter deposition.

In accordance with a further embodiment, the invention is directed towards an OLED device comprising a substrate having a first electrode and one or more organic layers formed thereon, at least one organic layer being a light-emitting layer; a conductive protective layer formed over the one or more organic layers opposite the first electrode wherein the resistivity of the protective layer is greater than 10⁶ ohm per square; and a sputter deposited second electrode formed over the conductive protective layer; wherein the device is made according to the process of the invention and wherein the organic layers are not thermally damaged during deposition of the conductive protective layer.

### Advantages

In accordance with various embodiments, the present invention provides a process for forming conductive protective layers over organic layers of an OLED element that can decrease damage due to electrode deposition, improve yields, particularly in the presence of particle contaminants, increase lifetime, and improve the efficiency of light emission.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a flow chart describing the steps of the present process;

FIG. 2 is a cross-section of an OLED device that may be prepared in accordance with an embodiment of the invention;

FIG. 3 is a diagram of an OLED device having a short caused by a defect in the OLED device organic layer; and

FIG. 4 is a diagram of an OLED device having a short-reduction layer preventing a short that would be caused by a defect in the OLED device organic layer.

### DETAILED DESCRIPTION OF THE INVENTION

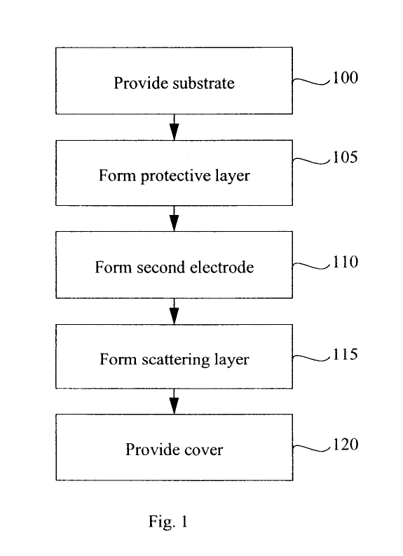

Referring to FIG. 1, a process for forming an OLED device, comprises the steps of providing 100 a substrate having a first electrode and one or more organic layers formed thereon, at least one organic layer being a light-emitting layer, forming 105 a conductive protective layer over the one or more organic layers opposite the first electrode by employing a vapor deposition process comprising alternately providing a first reactive gaseous material and a second reactive gaseous material, wherein the first reactive gaseous material is capable of reacting with the organic layers treated with the second reactive gaseous material, wherein the temperature of the gaseous materials and organic layers are less than 140 degrees C. while the gases are reacting and wherein the resistivity of the conductive protective layer is greater than 10⁶ ohm per square; and forming 110 a second electrode over the conductive protective layer by sputter deposition. Because of the relatively high resistance of the conductive protective layer, the conductive protective layer serves as a short reduction or prevention layer. The structure of the conductive protective layer caused by the vapor deposition process also serves to protect the organic layers from sputter damage and reduces the ingress of moisture into the organic layers.

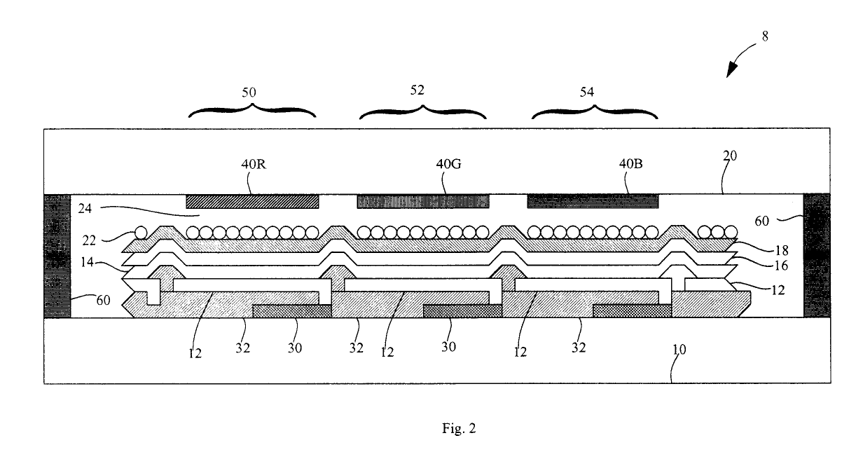

Referring to FIG. 2, an OLED device made according to an embodiment of the present invention comprises a substrate 10, a first electrode 12, one or more organic layers 14 over the first electrode 12, at least one organic layer 14 being a light-emitting layer, a conductive protective layer 16 and a second spaced-apart electrode 18. In a bottom-emitter embodiment of the present invention, the second electrode 18 or the conductive protective layer 16 may be reflective while the first electrode 12 is transparent. In a top-emitter embodiment of the present invention, the second electrode 18 and the conductive protective layer 16 are transparent. In this latter case, it is preferred that the conductive protective layer 16 has a refractive index equal to or greater than the refractive index of the one or more organic layers 14 but less than or equal to the refractive index of the second electrode 18. By providing such relative refractive indices, light emitted from the organic layers 14 will not be trapped in the organic layers 14 since light may travel from the organic layers 14 into the equal- or higher-index conductive protective layer 16. Likewise, light that travels into the conductive protective layer 16 will not be trapped therein since light may travel from the conductive protective layer 16 into the equal- or higher-index second electrode 18. Thin-film electronic components 30 having planarization layers 32 may be employed to control the OLED device, as is known in the art.

According to further embodiments of the present invention and as further illustrated in FIGS. 1 and 2, a scattering layer 22 may be formed 115 over the transparent second electrode 18 opposite the transparent conductive protective layer 16. The scattering layer 22 scatters trapped light in the transparent electrode 18, transparent conductive protective layer 16, and organic layers 14. A cover 20 is provided 125 over the OLED layers and adhered to the substrate 10 to protect the OLED device, for example using an adhesive 60. To maintain the sharpness of a pixilated OLED device, a low-index element 24 having a refractive index lower than the first and second refractive indices is formed between the transparent second electrode 18 and the transparent cover 20 as taught in US 2006/0186802 “OLED Device having Improved Light Output” by Cok et al, which is hereby incorporated in its entirety by reference. In some embodiments of the present invention, the light-emitting organic layer 14 may emit white light, in which case color filters 40R, 40G, 40B may be formed, for example on the cover 20, to filter light to provide a full-color light-emissive device having colored light-emitting elements 50, 52, 54.

According to the present invention, the conductive protective layer 16 is formed at a temperature less than 140 degrees C. In typical, prior-art atomic layer deposition or chemical vapor deposition processes, the substrate and any layers coated thereon are heated to relatively high temperatures, for example >200 degrees C. Such higher temperatures may be useful in increasing the conductivity of deposited layers. However, according to the present invention, a reduced conductivity is preferred as discussed below. In a more preferred embodiment of the present invention, the transparent conductive protective layer 16 is formed at a temperature less than or equal to 120 degrees C., less than or equal to 100 degrees C., or less than or equal to 80 degrees C. Applicants have demonstrated the deposition of a 100 nm thick transparent conductive protective layer of ZnO over a substrate of a top-emitter OLED device at a substrate temperature of 100 degrees C. using reactive gases as describe below at temperatures between room temperature and 100 degrees C.

A wide variety of materials may be employed to form the conductive protective layer 16, for example metal oxides, metal nitrides, or metal sulfides. In preferred embodiments, the conductive protective layer 16 comprises a zinc oxide, molybdenum oxide, indium tin oxide, silicon oxide, zinc sulfide, or silicon nitride. In general, metal oxide materials may have a conductivity that is higher than desired. To reduce the conductivity of the conductive protective layer 16, dopants may be employed.

In further embodiments of the present invention, the conductive protective layer 16 may provide a hermetic coating over the OLED elements to prevent the ingress of moisture to the organic layers 14 and thereby increase the lifetime of the OLED device.

The transparent electrode may also comprise a metal oxide, for example indium tin oxide or a doped metal oxide such as aluminum zinc oxide. In this case, it is possible that the transparent electrode may comprise at least some of the same materials as the conductive protective layer 16.

A variety of thicknesses may be employed for the conductive protective layer 16, depending on the subsequent processing of the device and environmental exposure. The thickness of the conductive protective layer 16 may be selected by controlling the number of sequentially deposited layers of reactive gases. In one embodiment of the present invention, the conductive protective layer 16 may be less than 400 nm thick, or more preferably, less than or equal to 100 nm thick.

According to the present invention, the conductive, protective layer 16 provides multiple functions. First, the conductive protection layer 16 is a conductive protective layer 16 has a relatively high resistance to prevent shorting defects in a light-emitting element of an OLED device 8 from conducting all of the available current in a light-emitting area so that no light is emitted from the area. By maintaining some current flow through other portions of the light-emitting element, some light will be emitted from the light-emitting element, even in the presence of the shorting defect. Second, the presence of the conductive, protective layer 16 over the organic layers 14, when deposited as claimed in the present invention, protects the organic layers from damage due to the sputter deposition of the second electrode 18. Third, the conductive, protective layer 16, when deposited as claimed in the present invention, may also provide resistance to the ingress of moisture to the organic layers, thereby improving the lifetime of the organic layers 14 and the OLED device 8.

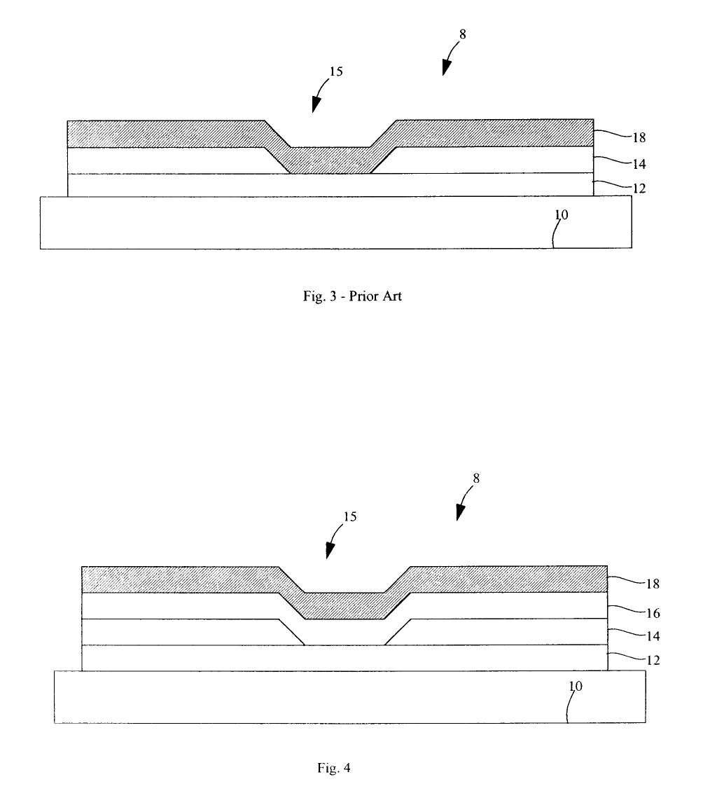

FIG. 3 shows schematically a shorting defect 15 in a prior-art OLED device 8. Device 8 includes a substrate 10, a first electrode 12, an organic EL element layer 14, and a second electrode 18. One of the electrode layers is the anode and the other electrode layer is the cathode. There are frequently other layers over the second electrode 18 for mechanical protection or other purposes, and often there is an organic or inorganic electron injection layer between the cathode and organic EL element 14 and an organic or inorganic hole injection layer between the anode and organic EL element 14.

For bottom emitting OLED devices, substrate 10 is transparent to the light emitted by OLED device 8. Common materials for substrate 10 are glass or plastic. First electrode 12 is also transparent to the emitted light. Common materials for first electrode 12 are transparent conductive oxides such as Indium-Tin Oxide (ITO) or Indium-Zinc Oxide (IZO), etc. Alternatively, first electrode 12 can be made of a semi-transparent metal such as Ag, Au, Mg, Ca, or alloys there of. When semitransparent metal is used as first electrode 12, OLED device 8 is said to have a microcavity structure. Organic EL element 14 includes at least a light emitting layer (LEL) but frequently also includes other functional layers such as an electron transport layer (ETL), a hole transport layer (HTL), an electron blocking layer (EBL), or a hole blocking layer (HBL), etc. The discussion that follows is independent of the number of functioning layers and independent of the materials selection for the organic EL element 14. Second electrode 18 is usually a reflecting metal layer such as Al, Ag, Au, Mg, Ca, or alloys thereof. Often a hole injection layer is added between organic EL element 14 and the anode and often an electron injection layer is added between organic EL element 14 and the cathode. In operation a positive electrical potential is applied to anode and a negative potential is applied to the cathode. Electrons are injected from the cathode into organic EL element 14 and driven by the applied electrical field to move toward the anode; holes are injected from the anode into organic EL element 14 and driven by the applied electrical field to move toward the cathode. When electrons and holes combine in organic EL element 14, light is generated and emitted by OLED device 8.

For top emitting OLED devices, light is emitted opposite to the direction of substrate 10. In such cases substrate 10 can be opaque to the emitted light and materials such as metal or Si can be used, the first electrode 12 can be opaque and reflective, and the second electrode 18 needs to be transparent or semitransparent.

Also shown schematically in FIG. 3, is a shorting defect 15 created by a region that has a lack of organic materials in organic EL element 14 due, for example, to inadequate deposition of organic materials on the first electrode 12. The discussion that follows also pertains to shorting defects caused by regions having substantially smaller thickness of organic materials in organic EL element 14 when compared with the rest of the device areas. There are many possible causes of shorting defects. For example, dust particles or flakes on the substrate 10 could locally block the flow of materials during the deposition of organic EL element 14 causing gaps or substantially smaller thicknesses in the organic films that leads to reduced electrical resistance between the first electrode 12 and the second electrode 18 deposition. The particles or flakes could come from the air before the substrates were loaded into the vacuum chamber or they could be generated during the first electrode 12 or organic deposition processes because of spitting of particles of source materials from the boat or because of de-lamination of deposits from the deposition chamber walls and fixtures. These particles or flakes may also fall off during or after the deposition of the organic layers because of mechanical vibration or stress in the organic deposits, or simply because of gravity. The particles or flakes that are present on the substrate 10 during the organic deposition process and subsequently fall off can cause the most damage. In this case they block the organic materials from depositing onto the substrate 10 and when they fall off they leave an area of the first electrode 12 completely exposed to the later deposition of the second electrode 18.

Other sources of shorting defects 15 include steps in the OLED device structure, for example those associated with the TFT (thin-film transistor) structure in an active matrix OLED display device, that cannot be completely covered by organic layers or rough textures on the surface of substrate 10 or the surface of first electrode 12. Shorting defect 15 causes second electrode 18 to contact directly or through a much smaller thickness of organic layers to first electrode 12 and provides a low resistance path to the device current. When an electrical voltage is applied between the anode and the cathode, a sizable electrical current, hereto referred to as a leakage current, can flow from the anode to the cathode through shorting defect 15 bypassing the defect free area of the device. Shorting defects can thereby substantially reduce the emission output of OLED device 8 and in many cases they can cause OLED device 8 to become not emitting altogether.

Referring to FIG. 4, when an OLED device 8 is constructed in accordance with the present invention, where there is a potential shorting defect 15 in organic EL element 14, second electrode 18 does not contact first electrode 12 directly in the pinhole 15, but through conductive protective layer 16. Conductive protective layer 16 when properly chosen can add a resistance term Rₛᵣₗ between first electrode 12 and second electrode 18 that substantially reduces the leakage current through shorting defect 15. The effectiveness of the present invention is analyzed as follows: let A be the area in cm² of OLED device 8, α be the total area in cm² of all shorting defects in OLED device 8, t be the thickness in centimeter and ρ be the bulk resistivity in ohms-cm of conductive protective layer 16, Iₒ be the operating current density in in Acm² and Vₒ be the operating voltage in volts of OLED device 8, the current that flows through the shorting defects can be calculated as:

$${I}_{σ} = 1000 \times \frac{{V}_{o}}{ρ \cdot \frac{t}{a}} = 1000 \times \frac{{aV}_{o}}{ρ t}$$

The conductive protective layer 16 reduces the negative impacts of shorting defect 15 and raises the device performance to an acceptable level. The negative impact of shorting defects can be measured by a parameter f, ratio of the leakage current that flows through the shorting defects to the total device current:

$$f = 1000 \times \frac{\frac{{aV}_{o}}{ρ t}}{{I}_{o} A} = 1000 \times \frac{{aV}_{o}}{ρ {tI}_{o} A}$$

To achieve an acceptable ratio fₒ, the conductive protective layer 16 needs to have a minimum through-thickness resistivity ρt of

$$ρ \cdot t \geq 1000 \times \frac{{aV}_{o}}{{f}_{o} {I}_{o} A}$$

The selection of materials that can be used as an effective conductive protective layer 16 depends therefore on the area A; the operating condition of OLED device 8, Vₒ and Iₒ; the level of performance loss that can be tolerated, fₒ; the total area of shorting defects, α; and the thickness of conductive protective layer 16, t, that can be incorporated into the device.

The thickness of conductive protective layer 16 is selected based on two considerations: 1). Typical OLED devices have total organic layer thickness of about 100-300 nm and the layer thickness is optically tuned to optimize the emission efficiency of the device. A conductive protective layer 16 becomes a part of the optical structure of the device and hence its thickness should not be over about 200 nm. Too thick a conductive protective layer also increases manufacturing cost of the OLED device. 2). The conductive protective layer needs to be thick enough to effectively cover the shorting defects. A reasonable lower limit is about 20 nm. The present invention prefers a conductive protective layer in the thickness range of 20 nm to 200 nm.

OLED devices are being used for many different applications. These OLED devices can have vastly different device area and operating conditions. For example, for lighting applications the OLED device tends to be divided into large light emitting segments (U.S. Pat. No. 6,693,296), greater than one centimeter squared, that operate at relatively few levels of current densities. For area color displays, the pixels are smaller, maybe on the order of square millimeters, and the operating conditions again do not varied a lot. For high resolution pixilated OLED displays, either on active matrix or passive matrix back planes, the pixels are much smaller, on the order of 0.3 mm×0.3 mm or smaller, and, in addition, the OLED devices need to provide a dynamic range. For an eight-bit resolution the device operating current needs to have a range of 1× to 256×. Equation 3 suggests that these different OLED devices will require vastly different materials as the conductive protective layer. US 2005/0225234 describes desired properties of short reduction layers in greater detail as may be used in the present invention, the disclosure of which is hereby incorporated in its entirety by reference.

For OLED displays or devices wherein the conductive protective layer is in the path of the emitted light, the layer needs to be reasonably transparent to the emitted light to effectively to function effectively as a conductive protective layer. For the purpose of the present application, reasonably transparent is defined as having 80% or more transmittance integrated over the emission bandwidth of the OLED device. If the conductive protective layer is not in the path of the emitted light then it does not have to be transparent. It may even be desirable to have the conductive protective layer also function as an antireflection layer for the reflecting anode or cathode to improve the contrast of an OLED display device.

While the conductive protective layer employed in the present invention has a resistivity of greater than or equal to 10⁶ ohms per square, it must also have sufficient conductivity to conduct current through the OLED device without greatly increasing the voltage required to drive the current through the device. In preferred embodiments, the resistivity of the protective layer is less than 10¹² ohms per square, or even less than 10¹¹ ohms per square, and in other specific embodiments the transparent conductive protective layer may have a resistance of less than or equal to 10¹⁰ ohms per square and more than or equal to 10⁸ ohms per square. The selection of resistance depends on the application of the device, and in particular on the area of each light-emitting element. In general, light-emitting elements having a relatively smaller area will require a conductive protective layer having a relatively higher resistance to serve as an effective short reduction layer.

Material for the conductive protective layer can include inorganic oxides such as indium oxide, gallium oxide, zinc oxide, tin oxide, molybdenum oxide, vanadium oxide, antimony oxide, bismuth oxide, rhenium oxide, tantalum oxide, tungsten oxide, niobium oxide, or nickel oxide. These oxides are electrically conductive because of non-stoichiometry. The resistivity of these materials depends on the degree of non-stoichiometry and mobility. These properties as well as optical transparency can be controlled by changing deposition conditions. The range of achievable resistivity and optical transparency can be further extended by impurity doping. Even larger range of properties can be obtained by mixing two or more of these oxides. For example, mixtures of indium oxide and tin oxide, indium oxide and zinc oxide, zinc oxide and tin oxide, or cadmium oxide and tin oxide have been the most commonly used transparent conductors.

Most of the prior art has been focusing on high conductivity transparent conductors having bulk resistivity values of 10⁻³ ohm-cm or less. These materials are too conductive to be used as conductive protective layers. High-resistivity thin-films have also been demonstrated using these oxides for applications such as gas sensors, antistatic coatings, etc. however. Higher resistivity thin-films can be prepared by changing the composition and deposition conditions away from those optimized for high conductivity transparent conductors. Higher resistivity can also be achieved in particular using materials containing molybdenum oxide, vanadium oxide, antimony oxide, bismuth oxide rhenium oxide, tantalum oxide, tungsten oxide, niobium oxide, or nickel oxide. By properly controlling deposition conditions and by combining these oxides and mixing with the more conductive oxides such as indium oxide, gallium oxide, zinc oxide, tin oxide, etc. a wide range of resistivity values can be obtained to cover the needs for both OLED device with large light emitting segments and high-resolution OLED display devices.

Other materials suitable for use as conductive protective layers include mixtures of a higher conductivity oxide material with an insulating materials selected from oxides, fluorides, nitrides, and sulfides. The resistivity of the mixture layer can be tuned to the desired range by adjusting the ratio of these two kinds of materials. For example, Pal et al. (A. M. Pal, A. J. Adorjan, P. D. Hambourger, J. A Dever, H. Fu American Physics Society, OFM96 conference abstracts CE.07) reported thin films made of a mixture of ITO with magnesium fluoride (MgF₂) covering a resistivity range of 3×10⁻⁵ to 3×10³ ohms-cm.

According to the present invention, the conductive protective layer 16 is deposited by vapor deposition. As used herein, vapor deposition refers to any deposition method that deposits a first reactive material onto a substrate. A subsequent second reactive material is then provided to react with the first reactive material. The process is repeated until an adequate multi-layer thickness is formed. For the description that follows, the term “gas” or “gaseous material” is used in a broad sense to encompass any of a range of vaporized or gaseous elements, compounds, or materials. Other terms used herein, such as: reactant, precursor, vacuum, and inert gas, for example, all have their conventional meanings as would be well understood by those skilled in the materials deposition art.

While prior-art atomic layer deposition processes may be employed, in one embodiment of the present invention, a moving, gas distribution manifold having a plurality of openings through which first and second reactive gases are pumped is translated over a substrate to form a conductive, protective layer 16. Co-pending, commonly assigned U.S. Ser. No. 11/392,007, filed Mar. 29, 2006, describes such a method in detail and the disclosure of which is hereby incorporated in its entirety by reference. However, the present invention may be employed with any of a variety of prior-art vapor deposition methods.

The conductive protective layer deposition process may employ a continuous (as opposed to pulsed) gaseous material distribution. The conductive protective layer deposition process cited above allows operation at atmospheric or near-atmospheric pressures as well as under vacuum and is capable of operating in an unsealed or open-air environment. Preferably, the protective layer deposition process proceeds at an internal pressure greater than 1/1000 atmosphere. More preferably, the transparent protective layer is formed at an internal pressure equal to or greater than one atmosphere. Various gases may be employed, including inert gases such as argon, air, or nitrogen. In any case, it is preferred that the gas be dry to avoid contaminating the organic materials with moisture.

A continuous supply of gaseous materials for the system may be provided for depositing a thin film of material on a substrate. A first molecular precursor or reactive gaseous material may be directed over the substrate and reacts therewith. In a next step, a flow with inert gas occurs over the area. Then, in one embodiment of the present invention, relative movement of the substrate and the distribution manifold may occur so that a second reactive gas from a second orifice in a distribution manifold may react with the first reactive gas deposited on the substrate. Alternatively, the first reactive gas may be removed from the deposition chamber and the second reactive gas provided in the chamber to react with the previous layer on the substrate to produce (theoretically) a monolayer of a desired material. Often in such processes, a first molecular precursor is a metal-containing compound in gas form, and the material deposited is a metal-containing compound, for example, an organometallic compound such as diethylzinc. In such an embodiment, the second molecular precursor can be, for example, a non-metallic oxidizing compound. Inert gases may be employed between the reactive gases to further ensure that gas contamination does not occur. The cycle is repeated as many times as is necessary to establish a desired film.

The primary purpose of the second molecular precursor is to condition the substrate surface back toward reactivity with the first molecular precursor. The second molecular precursor also provides material from the molecular gas to combine with metal at the surface, forming compounds such as an oxide, nitride, sulfide, etc, with the freshly deposited metal-containing precursor.

According to the present invention, it may not be necessary to use a vacuum purge to remove a molecular precursor after applying it to the substrate. Purge steps are expected by most researchers to be the most significant throughput-limiting step in ALD processes.

Assuming that, for example, two reactant gases AX and BY are used. When the reaction gas AX flow is supplied and flowed over a given substrate area, atoms of the reaction gas AX may be chemically adsorbed on a substrate, resulting in a layer of A and a surface of ligand X (associative chemisorptions). Then, the remaining reaction gas AX may be purged with an inert gas. Then, the flow of reaction gas BY, and a chemical reaction between AX (surface) and BY (gas) occurs, resulting in a molecular layer of AB on the substrate (dissociative chemisorptions). The remaining gas BY and by-products of the reaction are purged. The thickness of the thin film may be increased by repeating the process cycle many times.

Because the film can be deposited one monolayer at a time it tends to be conformal and have uniform thickness and will therefore tend to fill in all areas on the substrate, in particular in pinhole areas that may otherwise form shorts. Applicants have successfully demonstrated the deposition of a variety of thin-films, including zinc oxide films over organic layers. The films can vary in thickness, but films have been successfully grown at temperatures of 100 degrees C. and of thicknesses ranging from a few nanometers to 100 nm.

The vapor deposition process can been used to deposit a variety of materials, including SiO₂ and metal oxides and nitrides. Depending on the process, films can be amorphous, epitaxial or polycrystalline. Preferably, the films are structured such that moisture permeability is minimized, for example with more crystalline films. Thus, in various embodiments of the invention a broad variety of process chemistries may be practiced, providing a broad variety of final films. Binary compounds of metal oxides that can be formed, for example, are tantalum pentoxide, aluminum oxide, titanium oxide, niobium pentoxide, zirconium oxide, haffiium oxide, zinc oxide, lanthium oxide, yttrium oxide, cerium oxide, vanadium oxide, molybdenum oxide, manganese oxide, tin oxide, indium oxide, tungsten oxide, silicon dioxide, and the like.

Thus, oxides that can be made using the process of the present invention include, but are not limited to: Al₂O₃, TiO₂, Ta₂O₅, Nb₂O₅, ZrO₂, HfO₂, SnO₂, ZnO, La₂O₃, Y₂O₃, CeO₂, Sc₂O₃, Er₂O₃, V₂O₅, SiO₂, and In₂O₃. Nitrides that can be made using the process of the present invention include, but are not limited to: AlN, TaNₓ, NbN, TiN, MoN, ZrN, HfN, and GaN. Mixed structure oxides that can be made using the process of the present invention include, but are not limited to: AlTiNₓ, AlTiOₓ, AlHfOₓ, AlSiOₓ, and HfSiOₓ. Sulfides that can be made using the process of the present invention include, but are not limited to: ZnS, SrS, CaS, and PbS. Nanolaminates that can be made using the process of the present invention include, but are not limited to: HfO₂/Ta₂O₅, TiO₂/Ta₂O₅, TiO₂/Al₂O₃, ZnS/Al₂O₃, ATO (AlTiO), and the like. Doped materials that can be made using the process of the present invention include, but are not limited to: ZnO:Al, ZnS:Mn, SrS:Ce, Al₂O₃:Er, ZrO₂:Y and the like.

Various gaseous materials that may be reacted are also described in Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference. In Table V1.5.1 of the former reference, reactants for various ALD processes are listed, including a first metal-containing precursors of Group II, III, IV, V, VI and others. In the latter reference, Table IV lists precursor combinations used in various ALD thin-film processes.

Optionally, the present protective layer deposition process can be accomplished with the apparatus and system described in more detail in commonly assigned, copending U.S. Ser. No. 11/392,006, filed Mar. 29, 2006 by Levy et al. and entitled, “APPARATUS FOR ATOMIC LAYER DEPOSITION”, hereby incorporated by reference.

In a preferred embodiment, ALD can be performed at or near atmospheric pressure and over a broad range of ambient and substrate temperatures. Within the context of the present invention, however, temperatures equal to or less than 140° C. are required to avoid damage to organic layers. Preferably, a relatively clean environment is needed to minimize the likelihood of contamination; however, full “clean room” conditions or an inert gas-filled enclosure would not be required for obtaining good performance when using preferred embodiments of the process of the present invention.

OLED devices of this invention can employ various well-known optical effects in order to enhance their properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

The present invention may also be practiced with either active- or passive-matrix OLED devices. It may also be employed in display devices or in area illumination devices. In a preferred embodiment, the present invention is employed in a flat-panel OLED device composed of small-molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

The invention has been described in detail with particular reference to certain preferred embodiments thereof, but it will be understood that variations and modifications can be effected within the spirit and scope of the invention.

### PARTS LIST

8 OLED device
10 substrate
12 first electrode
14 organic element layer
15 shorting defect
16 conductive protective layer
18 second electrode
20 cover
22 scattering layer
30 thin-film electronic components
32 planarization layers
40R, 40G, 40B color filters
50 light-emitting element
52 light-emitting element
54 light-emitting element
60 adhesive
100 provide substrate
105 form protective layer step
110 form second electrode step
115 form scattering layer step
120 provide cover step

1. A process for forming an OLED device, comprising:
providing a substrate having a first electrode and one or more organic layers formed thereon, at least one organic layer being a light-emitting layer;
forming a conductive protective layer over the one or more organic layers opposite the first electrode by employing a vapor deposition process comprising alternately providing a first reactive gaseous material and a second reactive gaseous material, wherein the first reactive gaseous material is capable of reacting with the organic layers treated with the second reactive gaseous material, wherein the temperature of the gaseous materials and organic layers are less than 140 degrees C while the gases are reacting and wherein the resistivity of the protective layer is greater than 10⁶ ohm per square; and
forming a second electrode over the conductive protective layer by sputter deposition.

2. The process of claim 1, wherein the second electrode and the conductive protection layer are transparent

3. The process of claim 2 wherein the transparent conductive protective layer has a refractive index less than or equal to the refractive index of transparent second electrode.

4. The process of claim 2 wherein the transparent conductive protective layer has a refractive index greater than or equal to the refractive index of the one or more organic layers.

5. The process of claim 1, wherein the first electrode is transparent.

6. The process of claim 1 wherein the conductive protective layer has a resistivity of less than 10¹² ohms per square.

7. The process of claim 1 wherein the conductive protective layer has a resistivity of less than or equal to 10¹⁰ ohms per square and more than or equal to 10⁸ ohms per square.

8. The process of claim 1 wherein the conductive protective layer comprises a metal oxide, metal nitride, or metal sulfide.

9. The process of claim 1 wherein the conductive protective layer comprises a doped metal oxide and the dopant reduces the conductivity of the metal oxide.

10. The process of claim 1 wherein the conductive protective layer comprises a zinc oxide, molybdenum oxide, indium tin oxide, silicon oxide, zinc sulfide, or silicon nitride.

11. The process of claim 1 wherein the conductive protective layer is deposited upon the organic layers in a chamber having an atmosphere.

12. The process of claim 1 wherein the conductive protective layer is formed at an internal pressure substantially equal to or greater than one atmosphere.

13. The process of claim 1 wherein the conductive protective layer is formed at an internal atmosphere comprising nitrogen, argon, or air.

14. The process of claim 1 wherein the conductive protective layer is formed at a temperature less than 120 degrees C.

15. The process of claim 1 wherein the conductive protective layer provides a hermetic coating over the OLED elements.

16. The process of claim 1 wherein the conductive protective layer is less than or equal to 100 nm thick.

17. The process of claim 1 wherein the conductive protective layer is formed by employing one or more gas distribution manifolds that move with respect to the substrate.

18. The process of claim 1, wherein the vapor deposition process is an atomic layer deposition process.

19. An OLED device comprising a substrate having a first electrode and one or more organic layers formed thereon, at least one organic layer being a light-emitting layer; a conductive protective layer formed over the one or more organic layers opposite the first electrode wherein the resistivity of the protective layer is greater than 10⁶ ohm per square; and a sputter deposited second electrode formed over the conductive protective layer; wherein the device is made according to the process of claim 1 and wherein the organic layers are not thermally damaged during deposition of the conductive protective layer.
